(19) United States
(12) Patent Application Publication
(10) Pub. No.: US 2008/0214131 A1
(43) Pub. Date: Sep. 4, 2008

(54) User Interface to be Implemented in a Device for Organazing Broadcast Stations and Optically Their Content

(75) Inventor: Adolf Proidl, Bladel (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/996,368

(22) PCT Filed: Jul. 17, 2006
(86) PCT No.: PCT/IB06/52433

§ 371 Date: Jan. 22, 2008

(30) Foreign Application Priority Data
Jul. 22, 2005 (EP) 05106778.3

(51) Int. Cl. H03J 1/00

(52) U.S. Cl. 455/180.2

(57) ABSTRACT

This invention relates to a user interface to be implemented in a device, wherein the device comprises a tuner and a receiver for receiving broadcast signals from broadcast stations. The user interface uses semantic information associated with the received broadcast signals for sorting the received broadcast stations based on sorting criteria and displays the sorted broadcast stations on a display.

The present invention relates to a user interface to be implemented in a device and a method performed in the user interface, said device comprising a tuner and a receiver for receiving broadcast signals from broadcast stations, wherein said user interface is adapted to use semantic information associated with said received broadcast signals for sorting said received broadcast stations based on a sorting criteria and displaying said sorted broadcast stations.

From old radios it is known to show the names of radio stations and/or the location from where they are broadcasting on a user interface. In some modern cars, the radios comprise a large touch screen for displaying the name of more than one radio station on the screen.

EP-A-95564 discloses a mobile radio receiver, in particular a car radio receiver with direct program selection, which comprises, in an operating panel, program display surfaces and associated therewith selection keys for selecting the programs displayed. To obtain a small well laid-out operating panel which displays a plurality of radio programs receivable at different locations of the radio receiver, exchangeable program displays can be reproduced on the program display surfaces, this exchangeable program representing an up-to-date selection of the programs transmitted by stations having receiving quality at the current receiver location which satisfy predetermined receiving criteria, for example a predetermined received field strength.

U.S. Pat. No. 6,134,426 discloses a preferred solution of how to achieve such a reduction of an operating panel dynamically if only one tuner is available and the size of the user interface is very limited.

Both these references are focused on the visibility of the receivable broadcast stations and use only the transmission frequency as sorting criteria when displaying the receivable broadcast stations. Due to this, the situation can occur that if one and the same broadcast station broadcasts with several transmission frequencies, this one and the same broadcast station will be displayed several times on the same display.

There is therefore a need for a user interface to be implemented in e.g. car radios, which is more user oriented and makes use of other sorting criteria than said transmission frequency when selecting to sorting of said broadcast stations.

It is an object of the present invention to solve the above-mentioned problems by providing a user interface to be implemented in devices such as car radios and TV remote controls which uses semantic information associated to broadcasted signals for organizing a sorting of a receivable broadcast station and broadcast content and displays the result of the sorting on a display.

According to one aspect, the present invention relates to a user interface to be implemented in a device, said device comprising a tuner and a receiver for receiving broadcast signals from broadcast stations, wherein said user interface is adapted to use semantic information associated with said received broadcast signals for sorting said received broadcast stations based on a sorting criteria and displaying said sorted broadcast stations, said user interface comprises:

a communication unit for communicating with said receiver for receiving said semantic information, and

a processor operated based on said sorting criteria for using said semantic information for sorting said received broadcast stations and for displaying the result of said sorting on a display.

In that way, the user interface is no longer coupled to a frequency axis which enables said sorting of the received broadcast stations independent of the transmission frequency of said stations. Therefore, since the sorting is based on said semantic information and not on the transmission frequency, it is ensured that e.g. a broadcast station which transmits a broadcast signal with two frequencies will only be displayed once. Also, this enhances the sorting possibilities significantly and enables different sorting criterion, e.g. based on the type of the broadcast station (“jazz”, “rock”, “techno”, etc.), the name of the broadcast station (alphabetical sorting), beat per minute sorting, etc. Said broadcast stations can e.g. be radio broadcast stations, TV broadcast stations, internet broadcast station, etc., and said device can e.g. comprise a car radio, a TV remote control, PDA and the like.

In an embodiment, said user interface further comprises means for enabling said user to select a displayed broadcast station. Said means can e.g. comprise a touch screen function comprised in said display or a speech recognition system so that the user can select said displayed broadcast stations via touching or via a speech signal.

In an embodiment, said user interface further comprises an input means for receiving an input from the user indicating said sorting criteria and a memory for storing said received input from said user. This makes the user interface even more user friendly since the user himself/herself can decide which sorting criteria to select.

In an embodiment, said memory is further adapted to store broadcasted content from said broadcast stations. In that way, the user has the possibility to listen to a selected broadcast station although said broadcast station is no longer in a broadcast range or currently does not transmit the content of the selected type (e.g. music of the genre “smooth jazz”). This enables the user to e.g. maintain listening to his/her favorite radio station based on the stored content.

In an embodiment, wherein said processor is further adapted to initiate a playing of said stored content associated to a selected broadcast station when the signal of said selected broadcast station does not meet a specific criteria, e.g. is out of broadcast range, or when said selected broadcast station is currently not transmitting content of a user selected type. Therefore, if a user e.g. selects a radio station to listen to, which after some time is out of range or which has changed the broadcasted content, the live broadcast will automatically be shifted to the stored content (e.g. music with beets per minute below 100), which the user might even not notice.

In an embodiment, said user interface further comprises means for enabling the user to select two or more of said displayed broadcast stations. In that way, the user can, e.g. by touching/pressing or via a speech command, select different broadcast stations for different types of content and in that way customize his/her choice of broadcast stations without one broadcast frequency interrupts another broadcast frequency.

In an embodiment, said processor is further adapted to organize the playing of content segments from said two or more selected broadcast stations so that they do not overlap each other during playing. In that way, in case the user has selected said stations, the news will e.g. only be played between songs. As an example, in case the user interface is implemented in a car radio, the user can select one music station and one news station. Herewith the advantage is given that news and music can be received from different stations, and the station may belong to two different broadcast networks.

In an embodiment, said means for enabling said user to select a displayed broadcast station comprises a touch screen function comprised in said display. In that way, the user can in a very comfortable way select a broadcast station, e.g. a radio station (in case the user interface is implemented in a car radio) or a TV station (in case the user interface is implemented in a TV remote control). Preferably, said display is comprised in said devices, in this case in the car radio or the TV remote control.

In an embodiment, said user interface further comprises means for receiving additional content reproduced by said device and including said content as an additional artificial broadcast station. In that way, all the audible content that can be reproduced by a car radio at a particular point in time may be displayed at one glance in the user interface. This includes recorded content from broadcasting stations, music from the CD (changer) and music from a portable device being present in the car. This content is preferably presented so that it allows the user to maintain the overview of the choices, e.g. by genre or by station name (the CD changer gets an “artificial” station name like “CD changer”). As an example, the situation could further occur that the user is tuned to a radio station in the classic music area, but not to his/her portable music device. In such a situation the user is able to find the classic music of his/her portable device in the classic music section as a “portable device”. It should be noted that “artificial stations” can appear more than once in a user interface that does not allow multiple occurrences of “live” stations in the genre view.

According to another aspect, the present invention relates to a method performed in a user interface implemented in a device, said device comprising a tuner and a receiver for receiving broadcast signals from broadcast stations, wherein said user interface is adapted to use semantic information associated with said received broadcast signals for sorting said received broadcast stations based on a sorting criteria and displaying said sorted broadcast stations, said method comprising steps of:

communicating with said receiver for receiving said semantic information,

using said semantic information for sorting said received broadcast stations and for displaying the result of said sorting on a display.

In an embodiment, said broadcast stations comprise radio broadcast stations or TV broadcast stations.

In an embodiment, said semantic information comprises information from a group of information consisting of:

RDS call sign of said broadcast stations,

the beets per minute of the broadcasted music,

the RDS genre indicated by the broadcast station, and

the Digital Audio Broadcast (DAB) program guide information.

In an embodiment, said method further comprises the step of enabling the user to select said sorting criteria.

In an embodiment, said method further comprises the step of enabling the user to select one or more of the displayed broadcast stations. In that way, the user can customize his/her selection of broadcast stations.

The present invention further relates to a computer-readable medium having stored therein instructions for causing a processing unit to execute said methods.

These and other aspects of the invention will be apparent from and elucidated with reference to the embodiment(s) described hereinafter. In the following, preferred embodiments of the invention will be described referring to the figures, where

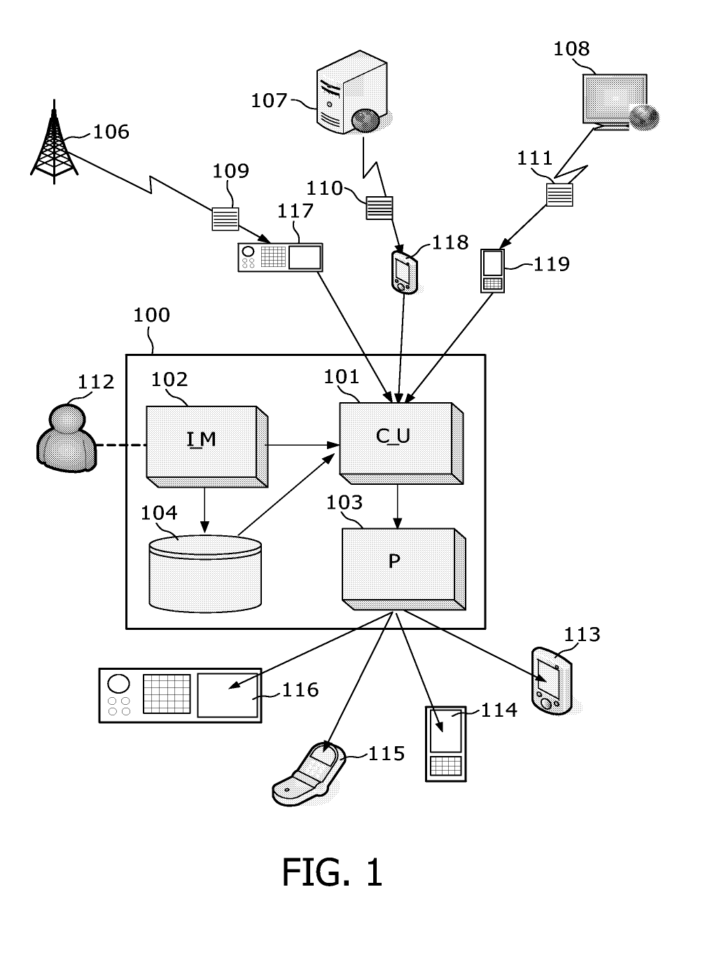

FIG. 1 shows a user interface according to the present invention which is to be implemented in devices,

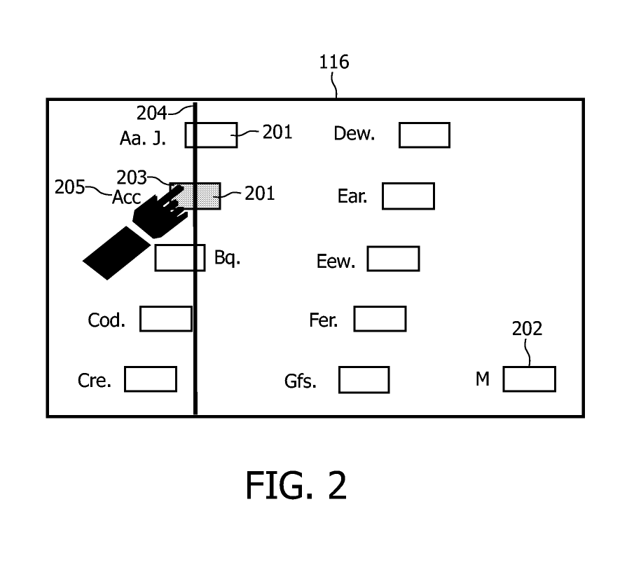

FIG. 2 shows an example implementation the user interface from FIG. 1 in a car radio,

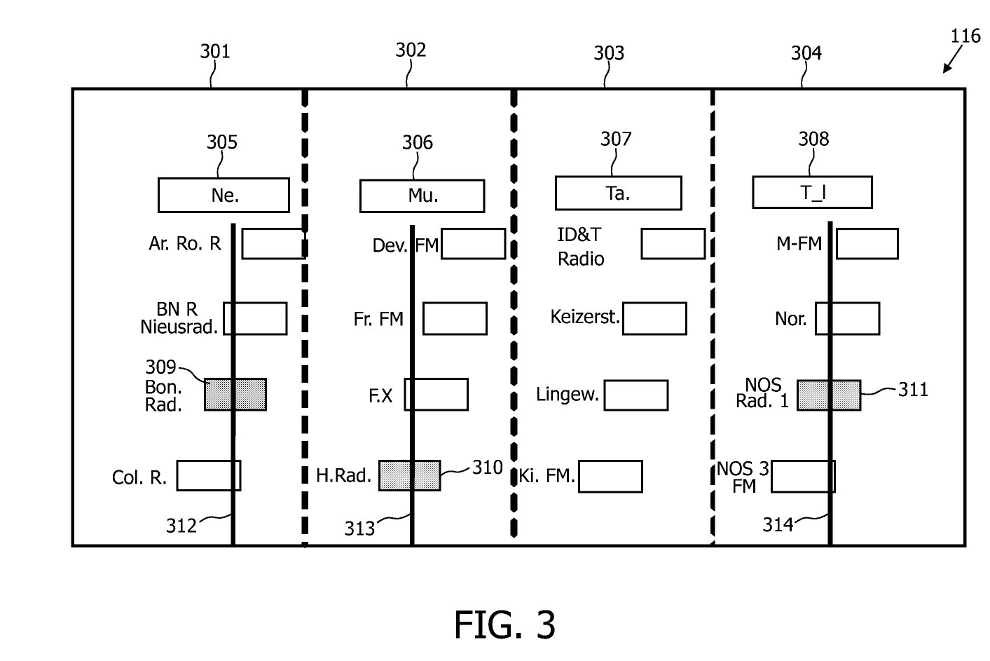

FIG. 3 shows another example of an implementation of the user interface from FIG. 1 in a car radio, and

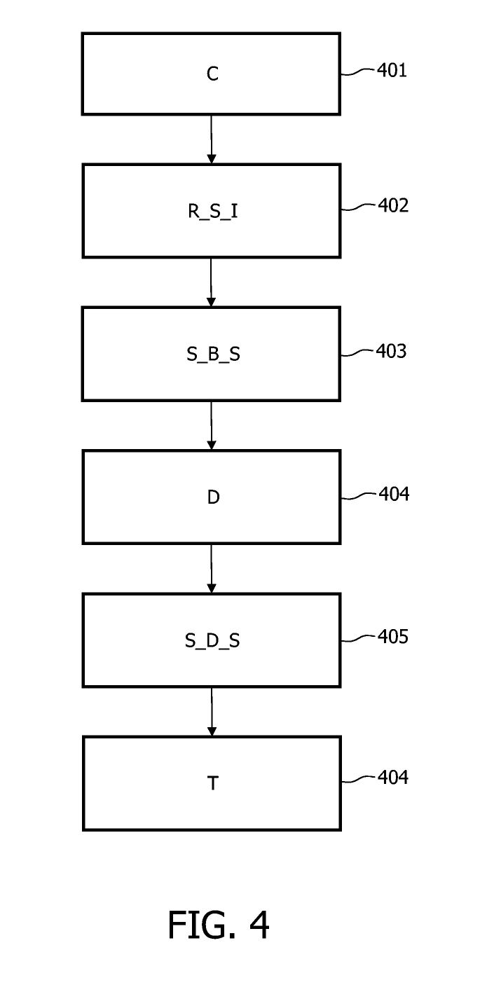

FIG. 4 illustrates a method according to the present invention performed in a user interface implemented in a device.

FIG. 1 shows a user interface 100 according to the present invention which is to be implemented in devices, e.g. remote controls 119, mobile devices such as PDA's 118 or mobile phones and car radios 117. According to the present invention, the user interface 100 uses semantic information 109-111 from broadcast signals broadcasted from broadcast stations, and which are received by said devices 117-119 to sort the stations or the content received by said stations and display the result of the sorting on a display 113-116 comprised in said devices 117-119. The broadcast stations can e.g. be radio stations 106, internet stations 107 and TV stations 108. Accordingly, said devices 117-119 must be provided with a tuner for tuning the frequency range of the broadcasted signals and a receiver for receiving the broadcasted signals. The semantic information can either be transmitted via the same broadcast channel or via a separate broadcast channel, e.g. another broadcast station or an internet site.

As an example, in case the user interface 100 is implemented in a car radio 117, one sorting criteria could be to sort all the received radio stations in alphabetical order and in that way decouple the tuning bar from the frequency of the horizontal axis. Also, in case the user interface 100 is implemented in a remote control, one sorting criteria could comprise sorting the received TV stations alphabetically or based on their content, e.g. “News”, “Movies”, “TV-shop”, etc., and display the sorting on a display 114 comprised in the remote control.

According to one embodiment of the present invention, the user interface 100 comprises an input means (I_M) 102 for receiving an input from the user 112 indicating said sorting criteria, a memory 104 for storing the selected sorting criteria, a communication unit (C_U) 101 for communicating with said devices 117-119 for receiving said semantic information 109-111 from the received broadcast signals, and a processor (P) 103 for processing the semantic information 109-111 for performing said sorting. Said processor (P) 103 is further adapted to control said display 113-116 for displaying the result of said sorting. The communication unit (C—U) 101 can comprise an 12C bus controller, a CAN bus controller or an UPnP control point/renderer.

In a preferred embodiment, the displays 113-116 comprise touch screen function for enabling the user 112 to select one or more broadcast stations, wherein the processor (P) 103 is further adapted to receive commands from the user 112 via touching a “touch button” on the display when selecting e.g. a displayed radio station.

In one embodiment, the input means (I_M) 102 is adapted to instruct the communication unit (C_U) 101 to retrieve the entire list of receivable broadcasting stations, which then triggers a scan for the available stations at the tuner and receiver comprised in said devices 117-119. In another embodiment, the tuner and the receiver are adapted to autonomously and continuously monitor the receivable frequency range for available stations and report any change in the available stations to the communication unit (C_U) 101 of the user interface. For instance, in case of UPnP control point/renderer the input means would once (typically at power up) request a complete list of receivable broadcast stations 106-108 via the communication unit (C_U) 101 from the broadcast reception means, and then subscribe, again via the communication unit (C_U) 101, to the updates on station availability change to be kept up to data.

The semantic information 109-111 can e.g. comprise the RDS call sign of the stations 106-108, the beets per minute of the music currently broadcast by the stations 106-108 (which could also be determined by processor (P) 103 or a processor connected to the broadcast reception means), the RDS genre indicated by the stations 106-108 or Digital Audio Broadcast (DAB) program guide information.

The input means 102 can e.g. comprise a touch screen function comprised in said displays 105, 113-116, wherein the user 112 can, simply by touching a displayed selection criterion, choose the sorting criteria. Other kinds of input means 101 are inherently also possible, such as a regular push button function comprised in the radio 117, a speech recognition system where the user 112 can make said sorting selection via a speech command.

In a preferred embodiment, said memory 104 is further adapted for storing broadcasted content such as music. The result obtained by storing broadcasted content is that the user interface 100 can collect music from one or more radio stations 106 and thereby enable the user 112 to play said stored music when e.g. said radio stations 106 do not broadcast the selected music genre at a particular point in time or are out of broadcast range, e.g. when the user 112 is traveling abroad in his/her car. Accordingly, said user interface 100 can even be adapted to switch automatically to a pre-stored music of a selected radio station when the radio station is no longer in a broadcast range or currently does not broadcast the desired type of content.

FIG. 2 shows an example implementation the user interface 100 from FIG. 1 in a car radio 117. The touch screen display 116 shows a number of radio stations marked by a number of buttons 201 which are sorted alphabetically by their RDS names. To select a station the user 112 may put his finger 203 on one of the displayed buttons 201, which results in that the tuning bar 204 moves to the selected button 201 (i.e. radio station).

Alternatively the user 112 may move his finger 203 over the display 116, resulting in that the tuning bar follows his/her finger 203 and tunes to the station associated to the selected button.

In an embodiment, all the audible content that can be reproduced by the car radio 117 at a particular point in time is displayed at one glance in the user interface 100 (this includes live broadcasting stations, recorded content from broadcasting stations, music from the CD (changer), music from a portable device being present in the car, etc.). This content is preferably presented so that it allows the user 112 to maintain the overview of the choices, e.g. by genre or by station name (the CD changer gets an “artificial” station name like “CD changer”). As an example, the situation could occur that the user 112 is tuned to a radio station in the classic music area, but not to his/her portable music device. In such a situation the user 112 would be able to find the classic music of his/her portable device in the classic music section, so in a way the portable music device appears as an artificial station, that is e.g. as a “portable device”. It should be noted that “artificial stations” can appear more than once in a user interface that does not allow multiple occurrences of “live” stations in the genre view.

By touching the “more” button 202, the subsequent radio stations will be played. In that way, the user 112 can “scroll” through e.g. the list of all available radio stations. If all the stations are visible at one glance, the “more” button 202 could be adapted to appear only in a “zoomed” in view of the user interface for facilitating the selection process.

In an embodiment, a light pressing of the finger 203 on one of the displayed buttons 201 tunes temporarily to the station the finger points to, wherein removing the finger 203 tunes back to the previous station.

In an embodiment, a harder pressing on one of said displayed button 201 tunes permanently to the frequency of the radio station associated to the button, i.e. by removing the finger 203 said frequency stays tuned.

In an embodiment, in cases of low resolution display, a magnification function is employed to magnify station names beneath the moving finger 203. For instance, if only the first three letters of the radio stations are shown, if the finger 203 is detected close to the display 114 (not touching yet) the stations beneath the finger are written out completely, e.g. “Acc” becomes “Accent FM” 205.

FIG. 3 shows another example of an implementation of the user interface 100 from FIG. 1 in a car radio 117, wherein the touch screen display 116 comprises four tuning bars or categories 301-304, wherein each of said categories 301-304 is characterized by a specific topic. As shown here the categories are News (Ne.) 305, Music (Mu.) 306, Talk (Ta.) 307 and Traffic info (T_I) 308. This is for allowing the user 112 to personalize his/her radio or content with respect to topics. As shown here, the user 112 can e.g. select one station from the “News” category (Bon. Rad.) 309, one from the “Music” category (H.rad) 310 and one from the “Traffic Info” category (NOS. Rad. 1) 311. The tuning axis shown here as vertical axis 312-314 could be implemented in order to show graphically which selection the user 112 has chosen.

In an embodiment, the music category contains alternative sources of music to the live broadcasting stations, e.g. the car's CD changer, or a portable MP3 player that is wirelessly connected (e.g. via BlueTooth) to the car's audio system. These alternative sources may then be listed by their name in the music category section of the user interface (e.g. as “CD changer”, “portable device”). This results in the advantage that the user 112 can interleave his personal music with live content, e.g. receive an hourly news update while commuting and listening to his CD collection from the changer, by simply selecting “CD changer” in the music category and a station with hourly news in the news category; all other categories are disabled in this case.

In a preferred embodiment, the user interface 100 is adapted to organize the playing of the selected categories so that the playing of one category will not be interrupted by another category. As an example, the user interface 100 is pre-programmed so that the news is only played between songs. Accordingly, if news is transmitted while a song is being played, it is stored in a memory (e.g. memory 104) and played after the song.

In one embodiment, said user 112 can select a set of his/her favorite radio stations 106 to listen to or to watch (in case the user interface is used in a TV remote control). As an example, if the user 112 selects said three radio stations 309-311, the selection further indicates that the broadcasted content of said stations is to be recorded, wherein these favorite stations will remain visible and therefore selectable in the user interface even if the car radio is out of the broadcasting range of said stations. The recorded content will be played when one or more of said stations are out of broadcast range. In that way, the user can be listening to live traffic news (the NOS. Rad._1 311 is within a broadcast range) but a recorded music (H.rad 310 I out of broadcast range). In another embodiment, if e.g. one of the favorite radio stations is out of range, the user interface 100 will automatically select another radio station which is within a broadcast range which has similar characteristics. As an example, if the user 112 has selected a jazz radio station which is out of range, the user interface 100 will select a new jazz station which is within the broadcast range. This automatic switching to a new radio station can be based on predefined criteria such as if there is not sufficient recorded content available, e.g. only two songs have been recorded from the music station H.rad 310, or there is a lack of storage space or tuners to record (all) favorite radio stations, the user interface 100 will select a new similar radio station. In that way, said predefined criteria can e.g. be that at least 50 songs must have been recorded.

Additionally, the content of radio stations 106 that broadcast over different media (e.g. analogue FM radio, analogue AM radio, digital satellite radio, digital terrestrial radio (e.g. DAB) or internet radio) can be recorded by making use of these different media. This results in the following advantages:

1) It is possible to divide the tuning load between the different available tuner receivers comprised in the device. For instance, a car radio 117 comprises 2 analogue FM tuners and a DAB tuner. The user 112 has selected two favorite radio stations and now selects a third favorite station that can only be received via the analogue FM tuner. By means of the semantic information 109-111 the user interface 100 will verify if one of the previously selected favorite stations can also be received via DAB, and if yes, reroutes the recording of this station to the DAB tuner, freeing one tuner for the recording of the new favorite station.

2) It is possible to complement recorded content of favorite stations with long range broadcasting to maintain a live character long range. For instance, a car radio user 112 has selected a particular station in the Netherlands as his/her favorite station. Content from this station was recorded and kept while the user 112 was driving in the Netherlands. Now the user 112 goes with his/her car on vacation in Spain. The favorite radio station cannot be received live in Spain, but the news of this favorite radio station can be downloaded from the station's web site on the Internet. As the car radio's tuning and reception means comprise a WiFi module, the car radio 117 will download the latest news of the favorite channel, whenever it is located within a WiFi hot stop. In this way, the user 112 can also enjoy actual content from his/her favorite radio station, and the range of the station is extended in this way. It can be mentioned that the above scenario 2) can also be adapted to provide personal, targeted commercials.

In another embodiment, the user interface 100 is used for a personal radio service. In such cases said sorting can comprise sorting the radio content into “blocks” or boxes which are displayed on a display in a similar way as indicated in FIG. 2, wherein each block comprises a play list. The sorting can e.g. be based on the number of beets per minute (in case the content is music) or into music categories, e.g. “Modern Jazz”, “Classic jazz”, “Techno”, new categories, etc. The selected block does therefore not comprise a mapping to a frequency of a radio station. Instead the selected block comprises a mapping to the specific play list to be played. This content is either provided from local storage (e.g. HDD) or via a network (e.g. UMTS, XM radio, Sirius radio, or the Internet).

FIG. 4 illustrates a method according to the present invention performed in a user interface 100 implemented in a device 117-119 of the type mentioned previously, said device comprising a tuner and a receiver for receiving broadcast signals from broadcast stations. According to said method, said user interface communicates with said device (C) 401 for receiving semantic information (R_S_I) 402 from the received broadcast signals. The received semantic information is then used for sorting the broadcast stations (S_B_S) 403 based on a sorting criteria which can either be a fixed criteria or a criteria selected by a user 112 of the user interface 100. The fixed criteria can e.g. comprise always sorting received radio stations alphabetically based on their RDS call sign, based on the RDS genre indicated by the broadcast stations or based on beats per minutes of the broadcasted music content. Finally, the result of the sorting is displayed (D) 404 to the user 112 on a display 113-116, which typically is the display comprised in said devices 117-119 and which preferably comprise a touch screen display.

In a preferred embodiment, the user interface 100 is further adapted to enabling the user to select one or more broadcast stations 106-108 from said displayed sorting (S_D_S) 405, whereby, in case the broadcast station is a radio broadcast station, a processor comprised in said user interface communicates with a frequency tuner comprised in said device for tuning to the frequency associated to the selected broadcast station. Therefore, the displayed broadcast stations are no longer coupled to the typical “frequency axis”.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word ‘comprising’ does not exclude the presence of other elements or steps than those listed in a claim. The invention can be implemented by means of hardware comprising several distinct elements, and by means of a suitably programmed computer. In a device claim enumerating several means, several of these means can be embodied by one and the same item of hardware. The mere fact that certain measures are recited in mutually different dependent claims does not indicate that a combination of these measures cannot be used to advantage.

1. A user interface to be implemented in a device that includes a tuner and a receiver for receiving broadcast signals from a plurality of broadcast stations said user interface comprising:
a communication unit for communicating with said receiver for receiving semantic information associated with the broadcast signals for sorting the broadcast stations based on a sorting criteria and displaying the sorted broadcast stations;
a processor for using said semantic information based on the sorting criteria for sorting he broadcast stations and displaying a result of the sorting,
means for receiving additional content reproduced by the device and including the content as an additional artificial broadcast station; and
means for enabling the user to select two or more of the broadcast stations, wherein the processor organizes the playing of content segments from the two or more selected broadcast stations without overlapping during a playback.

2. The user interface according to claim 1, further comprising means for enabling said user to select a displayed broadcast station, wherein by selecting said broadcast station said processor communicates with said tuner to tune to a frequency associated to the selected broadcast station.

3. The user interface according to claim 1, further comprising an input means for receiving an input from the user indicating said sorting criteria, and a memory for storing said received input from said user.

4. The user interface according to claim 3, wherein said memory is further adapted to store content from said broadcast stations.

5. The user interface according to claim 1, wherein said processor is further adapted to initiate a playing of said stored broadcast content associated with a selected broadcast station when the broadcast signal of said selected broadcast station does not meet a specific criteria or when said selected broadcast station is currently not transmitting content of a user selected type.

6. (canceled)

7. (canceled)

8. The user interface according to claim 1, said means for enabling said user to select a displayed broadcast station comprises a touch screen function comprised in a display.

9. (canceled)

10. A method performed in a user interface implemented in a device that includes a tuner and a receiver for receiving broadcast signals from broadcast stations, wherein said user interface is adapted to use semantic information associated with said received broadcast signals for sorting said received broadcast stations based on a sorting criteria and displaying said sorted broadcast stations, said method comprising:
communicating with said receiver for receiving said semantic information,
using said semantic information for sorting said received broadcast stations and for displaying the result of said sorting on a display,
receiving additional content reproduced by said device and including the additional content as an additional artificial broadcast station;
enabling the user to select two or more of the broadcast stations; and
organizing the playing of content segments from the two or more selected broadcast stations without overlapping during a playback.

11. The method according to claim 10, wherein said broadcast stations comprise one of radio broadcast stations and TV broadcast stations.

12. The method according to claim 10, wherein said semantic information comprises information from a group of information consisting of:
RDS call sign of said broadcast stations,
beats per minute of the broadcasted music,
the RDS genre indicated by the broadcast stations, and
the Digital Audio Broadcast (DAB) program guide information.

13. The method according to claim 10, further comprising enabling the user to select said sorting criteria.

14. The method according to claim 10, further comprising enabling the user to select the one or more of the displayed broadcast stations.

15. A computer-readable medium having stored therein instructions for causing a processing unit to execute a method according to claim 10.
